(19) United States
(12) Patent Application Publication
(10) Pub. No.: US 2024/0175130 A1
(43) Pub. Date: May 30, 2024

(54) HIGH-THROUGHPUT SILICON CARBIDE REACTOR

(71) Applicant: ASM IP Holding B.V., Almere (NL)

(72) Inventors: Hichem M’Saad, Paradise Valley, AZ (US); Ivo Johannes Raaijmakers, Amersfoort (NL); Xing Lin, Chandler, AZ (US); Wentao Wang, Chandler, AZ (US); Herbert Terhorst, Amersfoort (NL)

(21) Appl. No.: 18/523,021

(22) Filed: Nov. 29, 2023

Related U.S. Application Data
(60) Provisional application No. 63/428,884, filed on Nov. 30, 2022.

(51) Int. Cl. C23C 16/455; C23C 16/44; H01L 21/67; H01L 21/677

(52) U.S. Cl. CPC C23C 16/45546; C23C 16/4412; C23C 16/45553; C23C 16/45565; H01L 21/67098; H01L 21/67201; H01L 21/67248; H01L 21/67742

(57) ABSTRACT

Methods and systems for growing silicon carbide epitaxial layers are described. In one example, a reactor system with multiple reactor modules may include a heating load/lock chamber and a cooling load/lock chamber. In another example, a reactor may be heated by separate sets of coils inductively heating a susceptor, which heats graphite near one or more wafers. Multiple pyrometers may measure the temperature of the graphite walls at different locations. Based on temperature differences and/or temperature gradients, a temperature controller may adjust power provided to one or more sets of coils. In yet another example, separations between a wafer carrier and a wafer may be adjusted.

### CROSS-REFERENCE TO RELATED APPLICATION(S)

This application claims the benefit of U.S. Provisional Application 63/428,884 filed on Nov. 30, 2022, the entire contents of which are incorporated herein by reference.

### TECHNICAL FIELD

The present disclosure generally relates to an apparatus and a method for manufacturing semiconductor devices.

### BACKGROUND

As transportation technologies shift from internal combustion engines to electric motors, the demand for high power electrical devices is expected to increase. Silicon carbide may be used to improve the power handling capability of those electrical devices. For instance, silicon carbide-based MOSFET integrated circuits may handle significantly more voltage than similar size silicon-based MOSFET integrated circuits. Various hurdles exist in manufacturing silicon carbide devices including the high process temperatures of silicon carbide epitaxial growth reactors as well as maintaining consistent temperatures across wafers. Also, where multiple reactor modules are combined into a multi-process system, the high temperature requirements of the silicon carbide epitaxy processes can decrease throughput in the multi-process system.

### SUMMARY

The following presents a simplified summary of various aspects described herein. This summary is not an extensive overview, and is not intended to identify key or critical elements or to delineate the scope of the claims. The following summary merely presents some concepts in a simplified form as an introductory prelude to the more detailed description provided below.

One or more aspects address issues related to the processing of semiconductors with silicon carbide layers including one or more of throughput and control of the thickness of an epitaxially grown silicon carbide layer via one or more of control of precursor gasses and/or control of a reactor temperature.

In one aspect, a system may comprise a plurality of reactor modules configured to perform semiconductor processes on wafers; a plurality of loading/unloading stations; one or more load/lock chambers configured to modify a temperature of the wafers; a substrate handling chamber comprising a first substrate transfer assembly, wherein the first substrate transfer assembly is configured to transfer the wafers between the plurality of reactor modules and the one or more load/lock chambers; and a transfer chamber comprising a second substrate transfer assembly, wherein the second substrate transfer assembly is configured to transfer the wafers between the plurality of loading/unloading stations and the one or more load/lock chambers.

In another aspect, the system may comprise a reactor chamber comprising outer and inner walls; a wafer carrier configured to support one or more wafers; a spindle configured to rotate the wafer carrier; graphite walls above and below the wafer carrier, wherein the inner walls and the graphite walls define a gas flow path; a susceptor above and below the graphite walls; two or more coils configured to inductively heat the susceptor; a power supply configured to energize the coils; two or more pyrometers configured to measure temperatures of the graphite wall; and a temperature controller configured to control, based on the temperatures and via the power supply, power supplied to at least one of the coils. In a further aspect, the temperature controller may receive signals from three or more pyrometers and determine a temperature gradient across the graphite walls and use that temperature gradient to modify the power applied to the coils.

Additional aspects, configurations, embodiments, and examples are described in more detail below.

### BRIEF DESCRIPTION OF DRAWINGS

The present disclosure is illustrated by way of example and not limited in the accompanying figures in which like reference numerals indicate similar elements and in which:

FIG. 1 depicts a comparison between silicon epitaxial growth and silicon carbide epitaxial growth;

FIG. 2 depicts a comparison between silicon epitaxial growth and silicon carbide epitaxial growth showing relative process times;

FIG. 3 depicts an illustrative reactor system with multiple reactor modules according to aspects of the disclosure;

FIG. 4 is a flowchart showing an illustrative process for operating a reactor system according to aspects of the disclosure;

FIG. 5 depicts an illustrative reaction chamber according to aspects of the disclosure;

FIG. 6 is a flowchart showing an illustrative process for controlling temperature according to aspects of the disclosure;

FIG. 7 depicts an illustrative precursor gas supply system according to aspects of the disclosure;

FIG. 8 depicts a perspective of the precursor gas supply system of FIG. 7 according to aspects of the disclosure;

FIG. 9 depicts a plan view of an illustrative reaction chamber with a rotating wafer carrier according to aspects of the disclosure;

FIG. 10 is a flowchart showing illustrative processes for controlling flows of precursor gasses in a reaction chamber according to aspects of the disclosure;

FIG. 11A depicts a first example of wafers on a wafer carrier in a reaction chamber according to aspects of the disclosure. FIG. 11B depicts a second example of wafers on a wafer carrier in a reaction chamber according to aspects of the disclosure;

FIG. 12 depicts a third example of wafers on a wafer carrier in an illustrative reaction chamber according to aspects of the disclosure;

FIG. 13 depicts a flow pattern of precursor gasses around a wafer edge; according to aspects of the disclosure and

FIG. 14 is a flowchart showing an illustrative process for modifying a wafer carrier according to aspects of the disclosure.

It will be recognized by the skilled person in the art, given the benefit of this disclosure, that the exact arrangement, sizes and positioning of the components in the figures is not necessarily to scale or required.

### DETAILED DESCRIPTION

Certain aspects relate to improving the processing of silicon carbide for semiconductor devices. In some aspects, the improvements may pertain to increasing throughput of a reactor system having multiple reactor modules. In other aspects, the improvements may pertain to improving the evenness of silicon carbide growth across a wafer via improving the flow of precursor gasses in a reaction chamber. In yet further aspects, the improvements may pertain to improving the evenness of silicon carbide growth across a wafer via improving how temperature, in a reaction chamber, is controlled.

As used herein, the term structure can include a substrate and a layer. A structure can form part of a device, such as a device as described herein. Structures can undergo further processing steps (such as deposition, etching, cleaning, and the like) to form a device.

As used herein, the term substrate can refer to any underlying material or materials upon which a layer may be deposited. A substrate may include a bulk material, such as silicon (e.g., single-crystal silicon) or other semiconductor material, and may include one or more layers, such as native oxides or other layers, overlying or underlying the bulk material. Further, the substrate may include various topologies, such as recesses, lines, and the like formed within or on at least a portion of a layer and/or bulk material of the substrate. By way of particular examples, a substrate may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments, the substrate may comprise one or more dielectric materials including, but not limited to, oxides, nitrides, or oxynitrides. For example, the substrate may comprise a silicon oxide (e.g., SiO₂), a metal oxide (e.g., Al₂O₃), a silicon nitride (e.g., Si₃N₄), or a silicon oxynitride. In some embodiments of the disclosure, the substrate may comprise an engineered substrate wherein a surface semiconductor layer is disposed over a bulk support with an intervening buried oxide (BOX) disposed therebetween. Patterned substrates may include features formed into or onto a surface of the substrate; for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon, silicon germanium, germanium tin, germanium, or a III-V material. Polycrystalline or amorphous surfaces may include dielectric materials, such as oxides, oxynitrides, or nitrides, such as, for example, silicon oxides and silicon nitrides. In some cases, the substrate includes a layer comprising a metal, such as copper, cobalt, and the like.

As used herein, the term film may refer to any continuous or non-continuous structures and material, such as material deposited by the methods disclosed herein. For example, a film may include two-dimensional (2D) materials or partial or full molecular layers of partial or full atomic layers or clusters of atoms and/or molecules. A film may include material with pinholes, but still be at least partially continuous. The terms film and layer may be used interchangeably. In this disclosure, gas may include vaporized solid and/or liquid and may be constituted by a single gas or a mixture of gases, depending on the context. The terms precursor gas or precursor gasses may refer to a gas or gasses that participate in a chemical reaction that produces another compound. In one or more examples, precursor gasses are used to grow an epitaxial layer comprising silicon carbide. Precursor gasses may include a deposition gas or gasses, a dopant gas or gasses, or a combination of a deposition gas or gasses and a dopant gas or gasses.

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. Any sequence of computer-implementable instructions described in this disclosure may be considered to be an “algorithm” as those instructions are intended to solve one or more classes of problems or to perform one or more computations. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expression “at least one of a, b, and c” may include ‘a only’, ‘b only’, ‘c only’, ‘a and b’, ‘a and c’, ‘b and c’, and/or ‘all of a, b, and c’.

It is noted that various connections between elements are discussed in the following description. It is noted that these connections are general and, unless specified otherwise, may be direct or indirect, and that the specification is not intended to be limiting in this respect. As described herein, thresholds are referred to as being “satisfied” to generally encompass situations involving thresholds above increasing values as well as encompass situations involving thresholds below decreasing values. The term “satisfied” is used with thresholds to address when values have passed a threshold and then approaching the threshold from an opposite side as using terms such as “greater than”, “greater than or equal to”, “less than”, and “less than or equal to” can add ambiguity where a value repeatedly crosses a threshold.

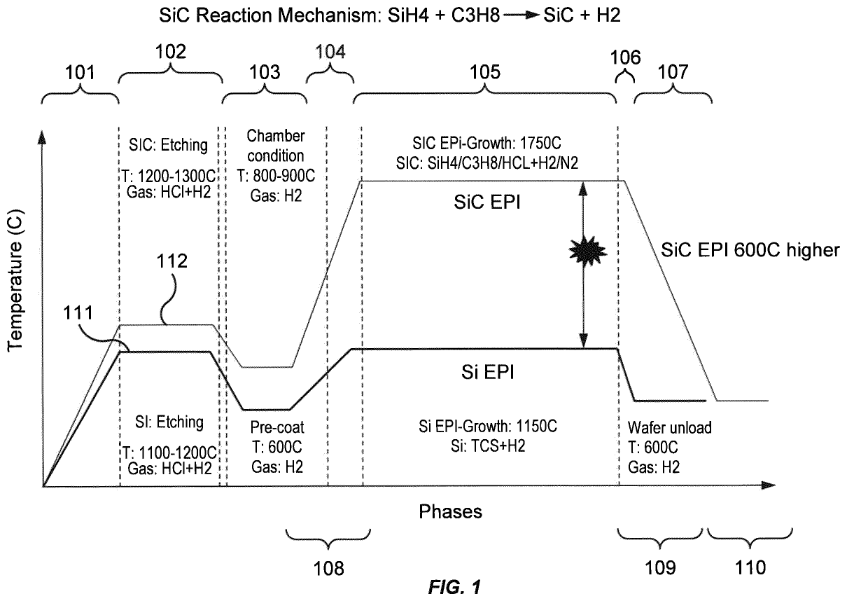

FIG. 1 depicts a comparison between silicon epitaxial growth and silicon carbide epitaxial growth in a reactor system over time. For silicon epitaxial growth as shown in process 111, a wafer is heated during phase 101 to operating etching temperature of between 1100-1200° C. In phase 102, the silicon wafer is etched in a hydrogen chloride (HCl) and hydrogen gas (H₂) environment. In phase 103, the wafer is pre-coded at a temperature of 600° C. in a hydrogen gas environment. In phase 104, the temperature of the environment is raised to 1150° C. In the silicon epitaxial growth phase 105, a silicon layer is epitaxially grown on the wafer in a trichlorosilane (TCS) and hydrogen gas environment. In phase 106, the wafer is cooled to 600° C. in a hydrogen gas environment. In phase 107, the wafer is unloaded.

FIG. 1 also shows a process 112 for epitaxial growth of silicon carbide on a wafer. During phase 101, the wafer is heated to a temperature in the range of 1200-1300° C. In phase 102, the wafer is etched in a hydrogen chloride and hydrogen gas environment. In phase 103, the chamber is conditioned for time interval at 800-900° C. in a hydrogen gas environment. In phase 108, the temperature of the environment is increased to 1750° C. While phase 104 of the silicon epitaxial growth process 111 is similar to phase 108 of the silicon carbide epitaxial growth process 112, phase 108 may require more time and is thus identified separately. In the silicon carbide epitaxial growth phase 105, a silicon carbide epitaxial layer is grown on the wafer in an environment of silane (SiH₄), propane (C₃H₈), hydrogen chloride (HCl), hydrogen (H₂), and nitrogen (N₂) as precursor gasses. For reference, the reaction mechanism for the silicon carbide epitaxial growth phase 105 may be represented as follows:

SiH₄+C₃H₈→SiC+H₂ Eq. 1

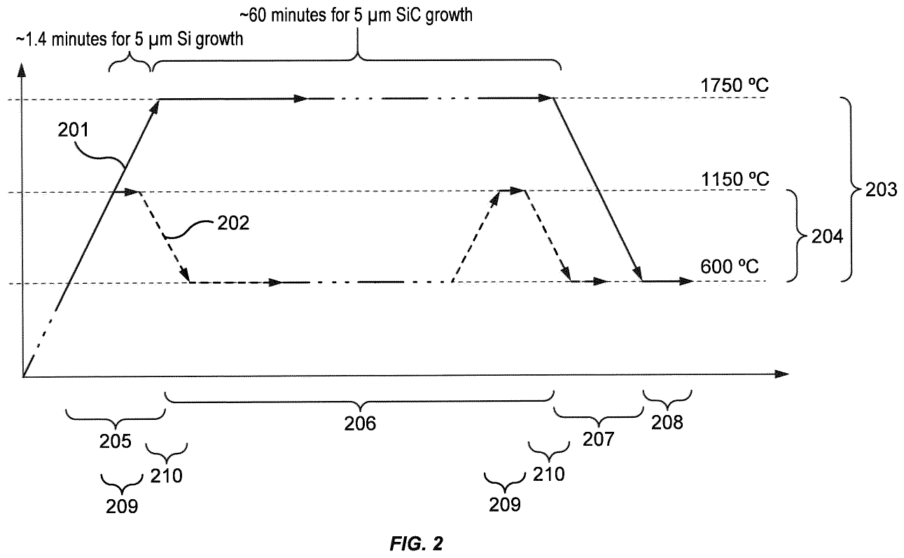

Of note, the silicon carbide epitaxial growth phase 105 occurs at 600° C. higher than the silicon epitaxial growth phase 105. In phase 109, the wafer is cooled to 600° C. in a hydrogen gas (H₂) environment and unloaded in phase 110. Also, as shown in FIG. 2, the epitaxial growth rate of silicon carbide is significantly longer than that of the epitaxial growth rate of silicon to grow an equivalent layer thickness.

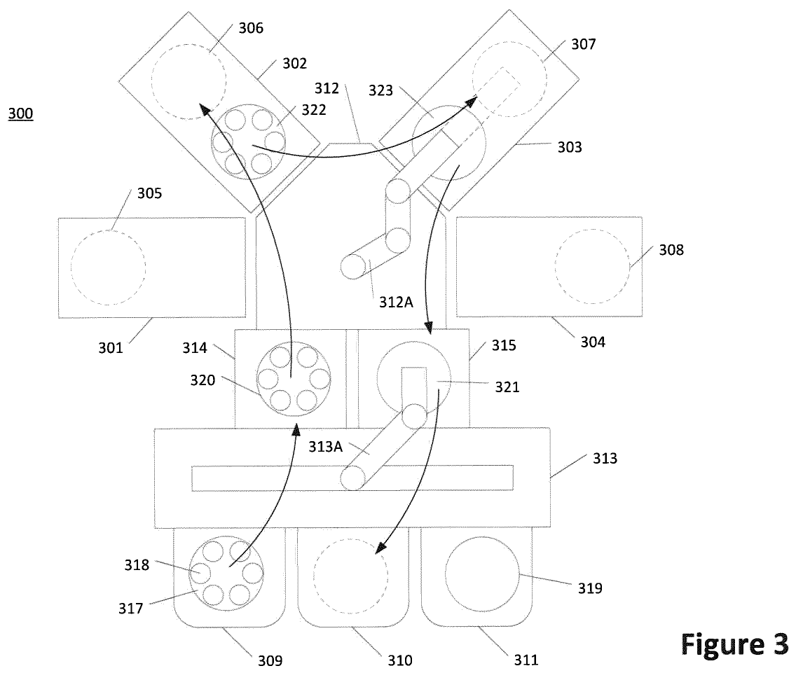

FIG. 2 depicts a comparison between silicon epitaxial growth and silicon carbide epitaxial growth, showing relative process times, in a reaction chamber. The silicon carbide epitaxy process is represented by solid arrows 201 and the silicon epitaxy process is represented by dotted arrows 202. The epitaxial growth rate of silicon carbide is approximately 42 times longer than the epitaxial growth rate of silicon to grow a layer of comparable thickness. For instance, to epitaxially grow 5 μm of silicon carbide, approximately 60 minutes is needed. In comparison, only approximately 1.4 minutes is needed to epitaxially grow 5 μm. Also, as shown at right on FIG. 2, the temperature range 203 for performing silicon carbide epitaxy ranges from 600° C. to 1750° C. In comparison, the temperature range 204 for performing the silicon epitaxy ranges from 600° C. to 1150° C. To provide a better understanding of the relative process times, the following examples relate to epitaxially growing 5 μm of silicon carbide and separately epitaxially growing 5 μm of silicon. For reference, the growth phases of FIG. 2 are shown relative to a reaction chamber. Where a load/lock chamber is used (e.g., as shown in FIG. 3), the load/lock chamber may raise the temperature from a room temperature (e.g., approximately 22° C.) to several hundred degrees higher (e.g., approximately 400° C.±50° C.) before being processed in the reaction chamber as shown in FIG. 2.

During the initial conditioning phase 205, the environment containing the wafer undergoing silicon carbide epitaxy is raised to 1750° C. During the silicon carbide epitaxial growth phase 206, the environment is held at that temperature for approximately 60 minutes to epitaxially grow the 5 μm of silicon carbide. At the end of the growth period, the temperature is lowered, during phase 207, to approximately 600° C. and the wafer unloaded during phase 208.

In comparison, a wafer undergoing silicon epitaxy for growing 5 μm of silicon has a much shorter cycle time. For example, during the preheating and initial conditioning phase 205, the environment for the silicon epitaxial growth is only raised to approximately 1150° C. In silicon epitaxial growth phase 209, a silicon epi layer is grown on the wafer. During phase 210, the environment is cooled to approximately 600° C. and the wafer with the silicon epi layer is subsequently unloaded. As shown in FIG. 2, the silicon epitaxial growth phase 209 is significantly shorter than the silicon carbide epitaxial growth phase 206. Based on the relative difference in epitaxial growth rates and required growth intervals, it is possible to perform multiple silicon epi processes on multiple wafers within the growth interval for growing the silicon carbide epi (e.g., as shown by the repeated heating, epi growth, and cooling phases of the silicon epi process 202). It is appreciated that epitaxial growth processes shown in FIG. 2 may be performed individually or in combination with other processes for further creating structures on the wafers. In other words, the loading and unloading of the wafers may be relative to a single epitaxial growth reactor module in a reactor system containing multiple reactor modules or may be relative to an individual reactor dedicated to performing epitaxial growth.

FIG. 3 depicts an illustrative reactor system with multiple reactor modules according to aspects of the disclosure. The reactor system 300 may comprise two or more reactor modules 301-304 configured to perform manufacturing processes on wafers (or combinations of wafers) at locations 305-308, respectively. By way of examples, reactor system 300 may be used to grow silicon carbide, etch, and/or deposit layers via one or more processes (e.g., using atomic layer deposition ALD, chemical vapor deposition CVD, or the like). The reactor modules 301-304 may include gas sources used as precursors and/or cleaners (e.g., used to clean a surface of a substrate and/or reduce metal oxides on the surface of the substrate before or after processing in a reactor module 301-304). Wafers may optionally be loaded and/or unloaded into the reactor system 300 at loading/unloading stations 309-311 or loaded directly to the process locations. The wafers may be provided individually or in groups on wafer carriers. For example, FIG. 3 shows, at loading/unloading station 309, a wafer carrier 317 supporting six wafers 318. Similarly, FIG. 3 shows, at loading/unloading station 311, a single wafer 319. The single wafer 319 may range in size from 100 mm (approximately 4 inches) to 300 mm (approximately 12 inches). The single wafer 319 may be supported by its own wafer carrier (not shown). Wafer carrier 317 may support two or more wafers (e.g., six wafers or another quantity). For instance, where the diameter of the wafer carrier 317 is approximately 300 mm and six wafers are supported by the wafer carrier 317, each of the six wafers may be approximately 100 mm (for close contact). Spacing the 100 mm wafers from each other expands the diameter of the wafer carrier 317 accordingly. For the same wafer carrier 317 with a diameter of approximately 300 mm, four wafers of approximately 125 mm may be supported. The size and quantity of the wafers 318 supported by the wafer carrier 317 may be varied as desired. For purposes of this disclosure, the wafer carrier 317 and/or a wafer carrier (not shown) supporting wafer 319 are referred to generally as a substrate carrier.

FIG. 3 also shows a substrate handling chamber 312, a heating load/lock chamber 314, and a cooling load/lock chamber 315. The heating load/lock chamber 314 and a cooling load/lock chamber 315 may each provide a combined functionality of acting as a loading position as wafers and/or wafer carriers are moved in and out of the substrate handling chamber 312 and/or between different reactor modules, providing a pressure lock between the substrate handling chamber 312 and a transfer chamber (described below as transfer chamber 313), and heating and/or cooling functions. For instance, the heating load/lock chamber 314 may raise a temperature of a wafer carrier from room temperature (e.g., approximately 22° C.) to several hundred degrees higher (e.g., approximately 400° C.±50° C.) before being provided to the substrate handling chamber 312. The cooling load/lock chamber 315 may cool the wafer carrier from the internal temperature inside the substrate handling chamber 312 to a lower temperature (e.g., to a temperature between room temperature and a temperature lower than the internal temperature of the substrate handling temperature 312). Substrate handling chamber 312 comprises one or more substrate transfer assemblies 312A (with one or more arms) configured to move substrate carriers and/or individual wafers between the heating load/lock chamber 314, the cooling load/lock chamber 315, and individual reactor modules 301-304. FIG. 3 further includes a transfer chamber 313 with one or more substrate transfer assemblies 313A configured to move substrate carriers or individual wafers between the loading/unloading stations 309-311, the heating load/lock chamber 314, and the cooling load/lock chamber 315. Each of the various chambers and modules of FIG. 3 may be sealed from each other (e.g., various doors and the like) and may be able to be separately pressurized or evacuated relative to each other.

A number of issues are present with the manufacturing of silicon carbide components: the slower epitaxial growth rate of silicon carbide (reducing the throughput of a manufacturing process); the increased operating temperatures required for silicon carbide epitaxy; and the sensitivity of silicon carbide to both temperature fluctuations and movement. One or more of those issues may be addressed by providing the separate heating load/lock chamber 314 and the separate cooling load/lock chamber 315.

For instance, the separate heating load/lock chamber 314 and the separate cooling load/lock chamber 315 in a reactor system 300 provide the ability to separately heat and/or cool the wafers to a different temperature separate from the wafer loading/unloading temperature. This is different from reactor systems that lack those separate heating and cooling chambers. For instance, as shown in FIG. 1, the wafer unloading temperature for both silicon carbide and silicon wafers is shown as 600° C. While 600° C. may be acceptable as a lower temperature across all phases 102-105 and 108 for silicon processes, silicon carbide benefits from a higher minimum temperature across all phases (e.g., 800-900° C. for phase 103 of silicon carbide compared to 600° C. for phase 103 of silicon). In short, the inclusion of the heating load/lock chamber 314 and the cooling load/lock chamber 315 enable the substrate handling chamber 312 to be maintained at a temperature higher than the temperature of the transfer chamber 313 and the loading/unloading stations 309-311. This separate temperature control provides a number of benefits. One benefit is the ability of manufacturers to use existing transfer chambers 313 and the loading/unloading stations 309-311 configured to operate at the lower silicon-based loading/unloading temperature of 600° C. while the rest of the reactor system 300 is maintained at a higher minimum temperature (e.g., 800-900° C.). Another benefit is minimizing potential damage to silicon carbide layers from larger temperature swings. Keeping a higher base temperature helps minimize cooling and reheating. A third advantage is improving throughput of a multiple process system as shown in FIG. 3. Heating and cooling silicon carbide wafers may require additional time. Forcing all reactor modules 301-304 to handle all heating and/or cooling operations consumes process time. With the separate heating load/lock chamber 314 and the cooling load/lock chamber 315, some of the heating and cooling process time may be moved from the individual reactor modules 301-304 permit those modules to start processing the wafers earlier and/or permit extraction of the wafers earlier than compared to where all heating and cooling was performed only in the individual reactor modules 301-304.

The heating load/lock chamber 314 may be dedicated to only heating wafers and the cooling load/lock chamber 315 may be dedicated to only cooling wafers. Alternatively, each may perform both functions (heating and cooling) as desired. The following example relates the heating load/lock chamber 314 being dedicated to heating and the cooling load/lock chamber 315 being dedicated to cooling. In this example, reactor modules 301 and 304 are not used. Five wafer carriers or wafers are being processed in various locations around reactor system 300. Wafer 321 has completed cooling and is being moved, via substrate transfer assembly 313A, from the cooling load/lock chamber 315 to the loading/unloading station 310. Once the cooling load/lock chamber 315 is available, the wafer 323 from the reactor module 303 is transferred, via substrate transfer assembly 312A, to the cooling load/lock chamber 315. Wafer carrier 322 in the reactor module 302 is moved, via the substrate transfer assembly 312A, to the reactor module 303. The wafer carrier 320 is then moved, via the substrate transfer assembly 312A, from the heating load/lock chamber 314 to the reactor module 302. Next, the wafer carrier 317 with wafers 318 is transferred, via the substrate transfer assembly 313A, from the loading/unloading station 309 to the heating load/lock chamber 314. By including the separate heating and cooling functions enabled by the heating load/lock chamber 314 and the cooling load/lock chamber 315, respectively, the overall process of changing the temperature of the wafers may be streamlined while minimizing thermal stress experienced by the wafers. A further advantage may include using a wafer carrier configured to retain heat while moving between reactor modules 301-304 and/or the heating load/lock chamber 314 and the cooling load/lock chamber 315. By retaining heat, wafers on the wafer carrier may be subject to less thermal stress when the wafer carrier is moved between regions of different temperature.

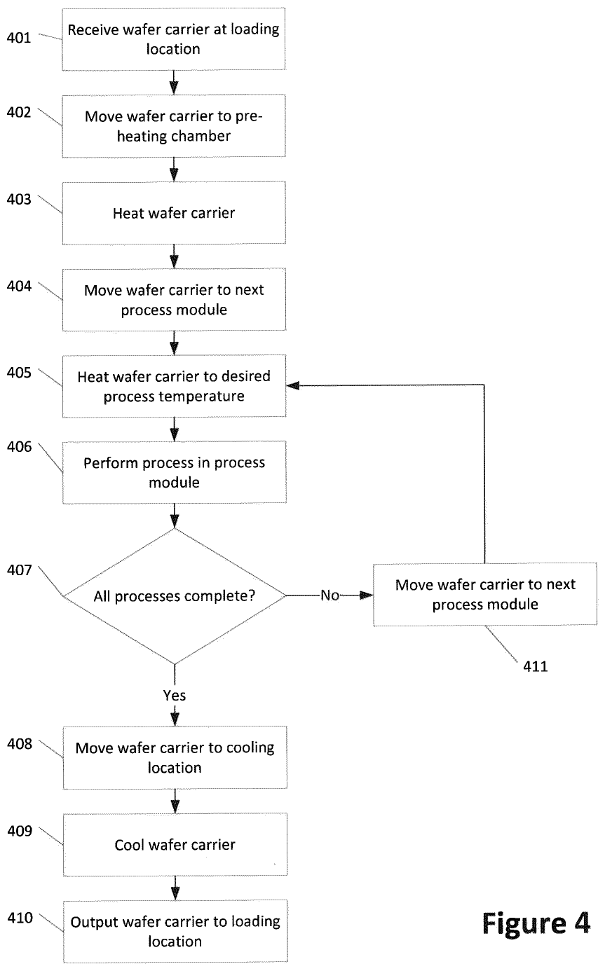

FIG. 4 is a flowchart showing an illustrative process for operating a reactor system according to aspects of the disclosure. In step 401, a wafer carrier may be received at a loading location. In step 402, the wafer carrier may be moved to a preheating chamber. In step 403, the wafer carrier (and the wafers supported by it) may be heated. In step 404, the wafer carrier may be moved to a reactor module. In step 405, the wafer may be heated in the reactor module to the temperature required for performance of a process. In step 406, the processes are performed on the wafers in the reactor module. In step 407, the system determines whether all processes are complete. If all processes are complete (step 407: Yes), the wafer carrier is moved to a cooling location in step 408 and it is cooled by the wafer carrier in step 409. Once cool, the wafer carrier may be output to a loading location in step 410. If, from step 407, all processes are not complete (step 407: No), then the wafer carrier is moved to the next reactor module, in step 411, and subsequent processing may be performed.

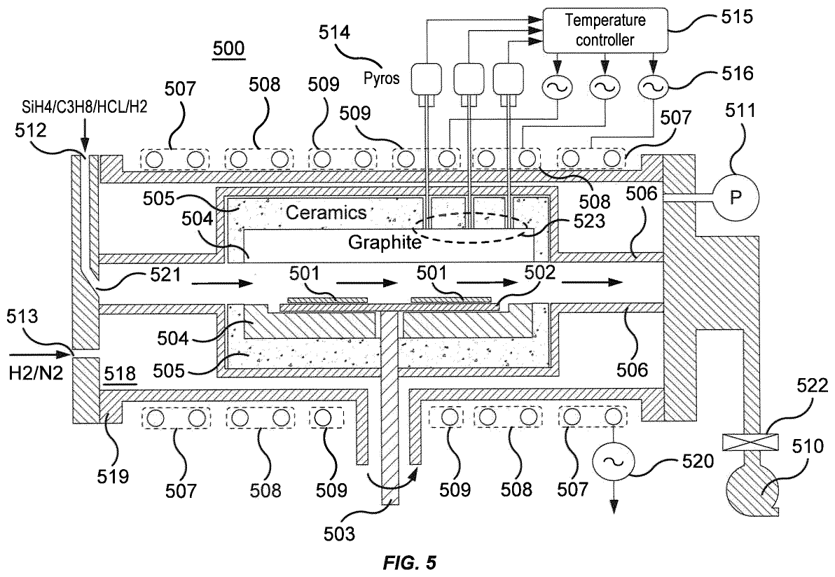

FIG. 5 depicts an illustrative reaction chamber for performing a high temperature process, e.g. silicon carbide epitaxial growth according to aspects of the disclosure. An issue with epitaxially growing silicon carbide is the variation in growth rates based on temperature. For instance, if one region of a wafer is exposed to a higher temperature than another region of the wafer, during the silicon carbide epitaxial growth process, the region exposed to the higher temperature may grow the epi layer more quickly than the region exposed to the lower temperature. This difference may be undesirable and lead to unacceptable layer thicknesses. One approach to measuring temperature of reaction chamber is to use a thermocouple located upstream or downstream from the wafers. Because of the potential for thermal variation across the wafers, thermocouples may not provide the instantaneous temperature readings required for consistent device processing. As described in FIG. 5, multiple pyrometers may be used to determine temperatures in a reaction chamber.

FIG. 5 shows wafers 501 on a wafer carrier 502 in a reaction chamber 500. The wafer carrier 502 is supported by and is caused to rotate about an axis by spindle 503. The wafer carrier 502 may be surrounded by upper and lower graphite walls 504. The graphite in the graphite walls 504 may help evenly distribute heat across the wafers. The graphite walls 504 may be contained within ceramic walls 505. The ceramic walls 505, acting as a susceptor, may be heated via inductive heating. For instance, sets of coils 507-509 may surround the exterior walls 519 of process chamber 518. The sense of coils 507-509 may be energized by a voltage generator 520 providing a radiofrequency alternating current voltage. The RF AC voltage passing through the coils 507-509 inductively heats the ceramic walls 505. Here, the ceramic walls 505 act as a subsector to the radiofrequency signal from coils 507-509. Various precursor gases 512 may flow from an injection flange 521, between inner walls 506 of the reaction chamber 500, across the wafers 501, and out of the reaction chamber 500 through an exhaust valve 522. The injection flange 521 may include one or more nozzles (not shown). The inner walls 506 define a flow path of the gas. The ceramic walls 505 and graphite walls 504 may further define the flow path of the gas. The flow of precursor gases across the wafers 501 may be aided by pump 510 by removing the gasses after flowing past the wafers 501. Pump 511 may separately adjust the ambient pressure within the reaction chamber 500. Additional gases may be provided via one or more nozzles 513 between the inner walls 506 and the exterior walls 519 of the process chamber.

FIG. 5 shows multiple pyrometers 514 measuring, at different locations, temperatures of the upper graphite wall 504 above the wafers 501. Outputs from the pyrometers 514 may be received and processed by a temperature controller 515. For instance, the temperature controller 515 may be a dedicated processor configured to convert signals from the pyrometers 514 into values representing temperatures from the various locations of the upper graphite wall of graphite walls 504. In one or more examples, the pyrometers 514 may be radially spaced from the axis of rotation of spindle 503 to measure temperatures of region 523 of the upper graphite wall 504. The temperature controller 515 may determine that one area of the region 523 of the upper graphite wall 504, and thus an area of the reaction chamber 500, is at a temperature higher or lower than desired. Using a temperature reading from one pyrometer, a temperature value may be compared against a range of desired temperatures for a given process. Using two temperature readings from two pyrometers, a temperature difference may be determined and compared against a maximum temperature difference threshold. Using three or more temperature readings from three or more pyrometers, a temperature gradient may be determined and compared against a maximum temperature gradient threshold.

Based on that determination, the temperature controller 515 may selectively provide more or less one or more excitation energy, via voltage sources 516 and/or 520, to one or more of coils 507-509. Voltage sources 516 and 520 may be operated in parallel or independently from each as needed. For instance, a dedicated transformer may be provided for each coil, where each coil is longitudinally offset from one another in the general direction of fluid flow through the reactor. A benefit of using pyrometers 514 may include closer to real-time measurements of temperatures proximate to the wafers 501. In one example, holes may be provided in upper graphite wall 504 to permit the pyrometers 514 to directly face the wafers 501 as they rotate on wafer carrier 502. In another example, no holes may be provided in the upper graphite wall 504 but only in the upper wall of the ceramic walls 505. The pyrometers 514 may only determine temperatures of regions of the upper graphite wall 504 instead of the actual temperatures of the wafers 501. While this latter example pertains to an indirect sensing of the temperatures around the wafers 501, this indirect sensing provides a benefit of maintaining a solid surface of the upper graphite wall 504 above the wafers 501, thereby removing potential thermal variations in the vicinity of the holes in the graphite wall 504 of the former example. Current frequency may be throttled according to (a) temperature difference from a single location, (b) temperature differential center-to-edge using measurements from two locations, and/or (c) temperature gradient center to edge using measurements from three locations.

Two pyrometers 514 may be used to determine a temperature variation between different regions of the graphite wall 504. Where one region is outside the temperature threshold (e.g., +/−2° C. from a target temperature) as determined by temperature controller 515, one or more of coils 507-509 may be selectively energized via voltage sources 516 to raise or lower the temperature of the region outside the temperature threshold.

In another example, three pyrometers 514 may be used to determine one or more temperature variations between different regions as described above. Additionally or alternatively, three pyrometers 514 may provide temperature readings to be used by the temperature controller 515 to identify temperatures at specific distances from the axis of rotation of the spindle 503. Based on the combination of the temperatures and distances, one or more curves may be fitted to the values. From the curves, one or more tangents of the curves may be determined. From the tangents, maximum and minimum slopes may be determined with the maximum slope representing the highest temperature gradient across the graphite and, relatedly, the wafers. Based on the highest temperature gradient, the temperature controller 515 may attempt to selectively modulate the power provided by voltage sources 516 to coils 507-509 to reduce the temperature gradient across the wafers 501. Further, four or more pyrometers 514 may be used by the temperature controller 515 to further determine additional temperature gradients across the wafers and adjust the voltage sources 516 accordingly.

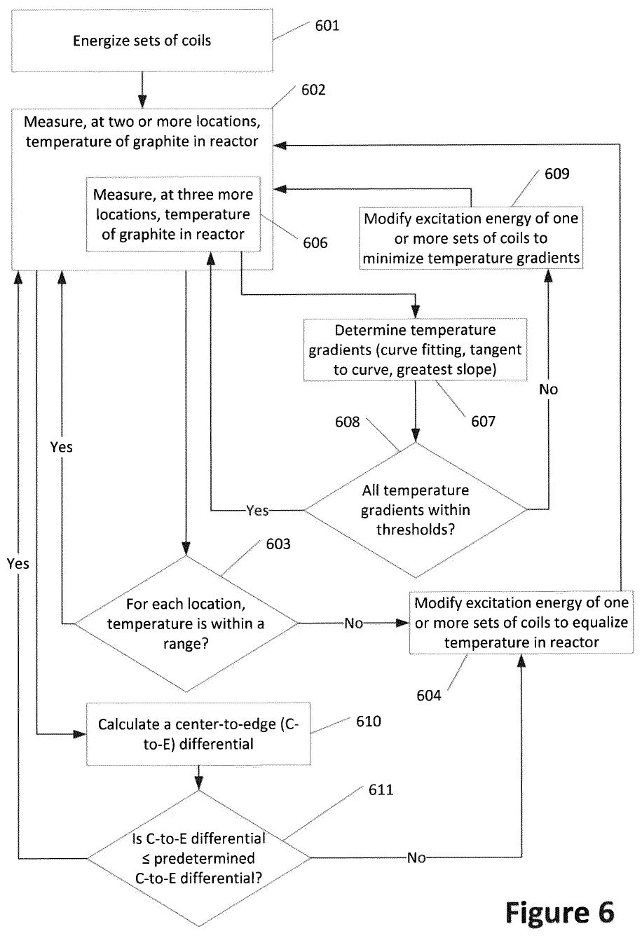

FIG. 6 is a flowchart showing an illustrative process for controlling temperature according to aspects of the disclosure. FIG. 6 shows an example of a process for adjusting the temperatures across wafers. In step 601, a temperature controller energizes sets of coils. In step 602, temperatures at two locations of graphite in a reactor are measured by pyrometers. In step 603, for each location, a temperature controller determines whether the temperature as measured by a pyrometer is within a range of temperatures. If the temperature for every pyrometer is within the desired temperature range (step 603: Yes), the process continues to monitor the temperatures in step 602. If any temperature is outside the range (step 603: No), the temperature controller modifies, in step 604, an excitation energy of one or more sets of coils to equalize the temperature in the reactor and continues to monitor the temperature in step 602. The combination of steps 603 and 604 may be referred to as a pointwise control of temperature.

Alternatively or additionally, three or more pyrometers may be used (as shown in nested step 606) to provide readings to the temperature controller. Based on the readings from the three or more pyrometers, the temperature controller may determine one or more temperature gradients in the vicinity of the wafers in the reactor. For instance, the temperature controller may determine the one or more gradients across the wafers (e.g., edge-to-edge, center-to-edge, etc.) and/or temperature gradients from the by attempting to fit a curve to three or more of the measured values, determine tangents to the curve, and determine a greatest slope of the tangents. Based on the determination of the greatest slope, the temperature controller may determine, in step 608, whether all temperature gradients are within threshold. If all temperature gradients are within a temperature gradient threshold (step 608: Yes), the temperatures are continued to be monitored in step 606. If one or more temperature gradients are outside the temperature gradient threshold (step 608: No), the temperature controller may modify, in step 609, excitation energies of one or more sets of coils to minimize the temperature gradients at the radial locations of the tangent lines with the greatest slopes.

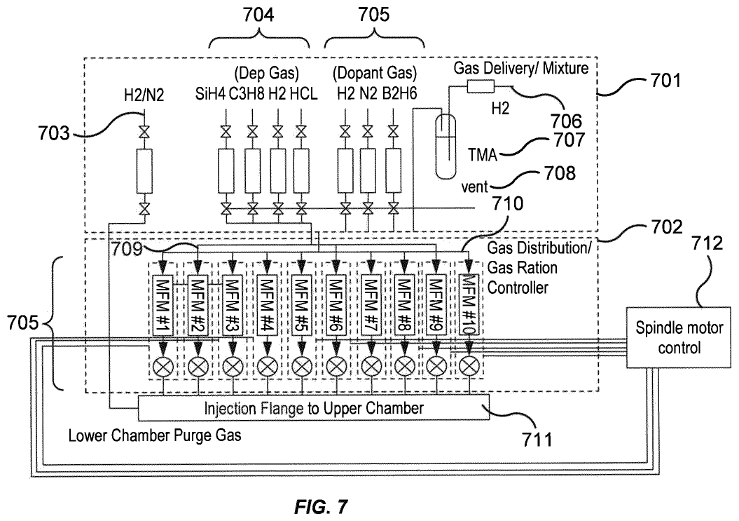

Alternatively or additionally, two temperature may be monitored in step 602 where the locations are the center and edge locations of the wafer/wafer carrier. A center-to-edge (C-to-E) differential may be determined in step 610. In step 611, the center-to-edge differential may be compared to a predetermined center-to-edge differential to determine whether the measured center-to-edge differential has the same or a smaller differential. If the measured differential is the same or smaller than the predetermined center-to-edge differential (step 611: Yes), then in the process continues to monitor the temperatures. If the measured differential is greater than the predetermined center-to-edge differential (step 611: No), the temperature controller modifies, in step 604, an excitation energy of one or more sets of coils to equalize the temperature in the reactor and continues to monitor the temperature in step 602. For example, a non-zero differential target may be used as the predetermined center-to-edge differential. Further, the predetermined center-to-edge differential compared in step 611 may be a maximum differential (only an upper threshold) or may be a desired range (both upper and lower thresholds). A benefit of using both an upper and lower threshold is to prevent an errant situation where the processor only corrects for one type of temperature differential (hot center to cold edge) but does not correct for another type of temperature differential (cold center to hot edge). Alternatively, where one of these types of temperature differentials can be eliminated via other means (e.g., better thermal regulation upstream), then the range (two thresholds) may be simplified to only one threshold). FIG. 7 depicts an illustrative precursor gas supply system for a reaction chamber according to aspects of the disclosure. The precursor gas supply system may include a gas delivery/mixture controller 701 and a gas distribution/gas ratio controller 702. In the gas delivery/mixture controller 701, a purge gas or gasses (e.g., hydrogen H₂ and/or nitrogen N₂) 703 may be supplied via a mass flow meter, mass flow valve, and dedicated controller to an injection flange 711 that injects gas into an upper chamber of a reactor. The gas delivery/mixture controller 701 may further supply precursor gases as deposition gases 704 and dopant gases 705. For example, the deposition gases may comprise silane SiH₄, propane C₃H₈, hydrogen H₂, and/or hydrogen chloride HCl and/or other gases. The dopant gases may comprise hydrogen H₂, nitrogen N₂, diborane B₂H₆, and/or other gasses. Further, hydrogen H₂ may be separately supplied 706 with trimethylamine (TMA) 707. One or more vents 708 may further be provided.

Each of the gas lines may include dedicated mass flow meters, mass flow valves, and controllers. Each of the controllers may be set-point controllers such that a set flow rate of that particular gas may be provided to the controller for a given portion of a process. Each controller may continually monitor the flow rate of its gas, compare that flow rate to the desired flow rate, and modify the flow rate, via the mass flow valve, to drive the flow rate to comport with the desired flow rate.

The gas distribution/gas ratio controller 702 may further control the mixture of the deposition gas 704 and the dopant gas 705 relative to each other. For instance, in the example of FIG. 7, ten separate gas flow lines may provide deposition gas to the injection flange 711. Each gas flow line may contain its own dedicated mass flow, meter mass flow valve, and controller. Each controller may be provided with a desired gas flow rate for its gas for particular portion of the process and adjust the flow rate of its gas accordingly.

As shown in FIG. 7, the deposition gas 704 is provided to mass flow meters 2, 6, and 9 and the dopant gas 705 is provided to mass flow meters 1, 3-5, 7-8, and 10. While the mass flow meters of FIG. 7 appear in order, the locations of the corresponding nozzles of the gas lines in the injection flange 711 may be modified, stacked, and/or varied as desired.

The precursor gas controller of FIG. 7 may provide the precursor gases to the injection flange 711 as described above. Alternatively, as an additional option, a position indication of a rotation position of the spindle motor 712 may be provided to one or more dedicated controllers on the gas lines of the gas distribution/gas ratio controller 702. Where the position indication is used, the dedicated controllers may selectively vary the output of their gas based on the current position and/or upcoming position of a given wafer. For instance, the timing of modulating the output of a given gas supply may be adjusted based on a velocity of the gas through the chamber. Where growth on one of a leading edge or trailing edge of a wafer during rotation is outside a thickness threshold, the output of a given nozzle may be modulated to increase or decrease the flow rate of that gas to provide more or less available precursor gas for that edge of the wafer while passing through the gas stream in the reaction chamber.

The flow rates of the gases may be adjusted to compensate for the radial distance of a portion of a wafer from the axis of rotation of the spindle. For instance, as a portion of a wafer farthest from the axis of rotation travels at a higher velocity than a portion of the wafer near the axis of rotation, providing the same concentration of gases over the surface of the wafer carrier may result in uneven growth rates as a larger surface area of the wafers at the periphery of the wafer carrier are competing for the same atoms in the precursor gases compared to a smaller surface area of the wafers near the center of the wafer carrier. Further the rotational velocity of the wafer carrier may adversely affect growth rates across each wafer. To address the various growth rates, different values may be provided to the dedicated controllers to change the volume of each gas provided to the injection flange 711 to equalize the growth rates across the surfaces of the wafers.

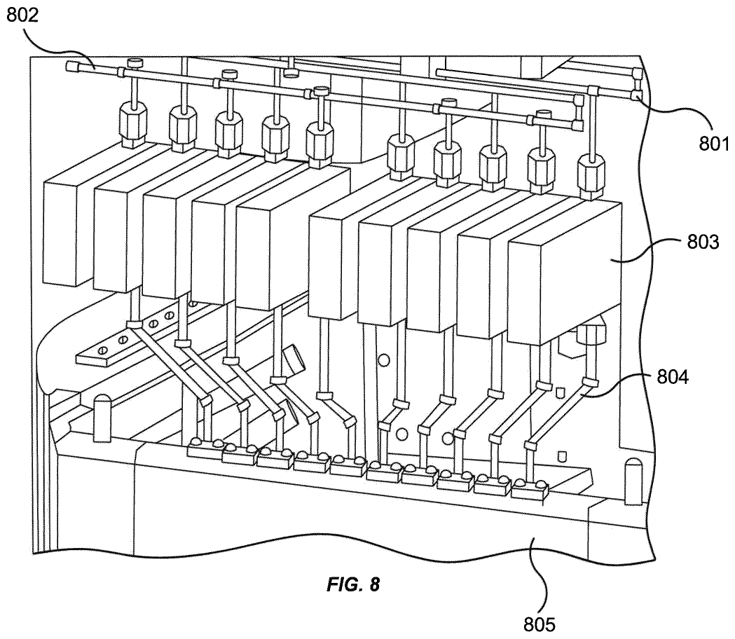

FIG. 8 depicts a precursor gas supply system according to aspects of the disclosure. FIG. 8 shows another view of the gas distribution/gas ratio controller 702 of FIG. 7. FIG. 8 shows a first gas supply line 801 and a second gas supply line 802, each selectively coupled to various ones of containers 803. Each of containers 803 includes a mass flow meter, a mass flow valve, and a dedicated controller receiving, for a portion of a process, a flow rate value for its particular gas. The output of each of containers 803 is fed to a reaction chamber (not shown) via lines 804 and injection flange 805.

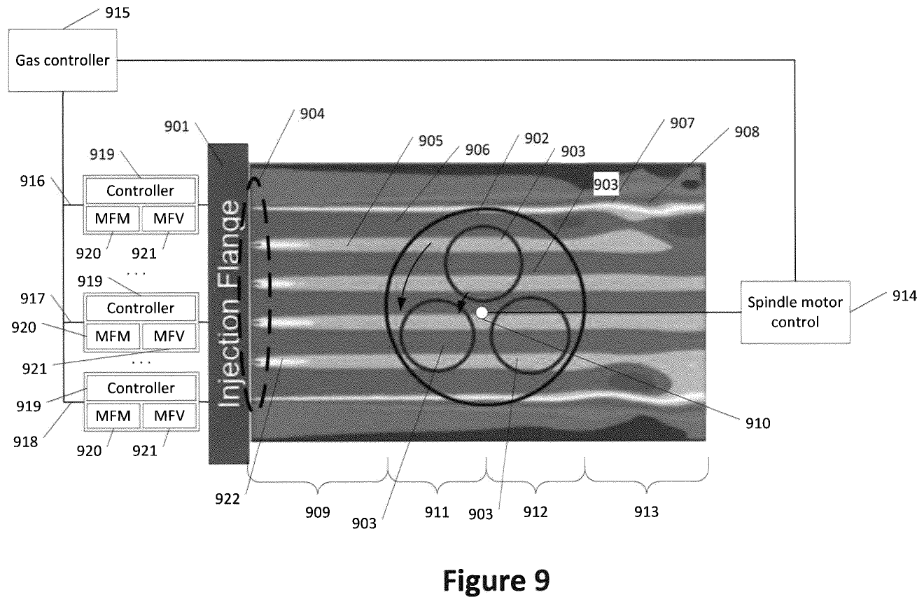

FIG. 9 depicts a plan view of an illustrative reaction chamber with a rotating wafer carrier according to aspects of the disclosure. FIG. 9 shows a plan view of an injection flange 901 with nozzles 904 providing dopant and deposition gases to a reaction chamber. A wafer carrier 902 with three wafers 903 is shown undergoing a process in the reaction chamber. A flow of gas from a nozzle is shown as stream 905. Areas in their reactor with lower gas concentrations are shown as regions 906. While beginning portions of gas streams are regular, irregularities begin to appear as shown by fluctuations 907 and 908. The beginning portion of the gas streams are shown in region 909. Those gas streams remain fairly regular while passing over a front portion 911 of the wafer carrier 902 and over a rear portion 912. Eventually, the gas streams become irregular as shown in region 913. Wafer carrier 902 rotates about an axis of spindle 910. The rotation of spindle 910 is controlled by spindle motor control 914. A position indicator from spindle motor control 914 may be provided to a gas controller 915. As shown in FIG. 9, each of the gas flow lines 916-918 includes an individual controller 919, a mass flow meter 920, and a mass flow valve 921. Using a setpoint flowrate value provided to a controller 919, the controller 919 adjusts the gas flowing through the mass flow valve 921, as measured by the mass flow meter 920, to comport with the setpoint flowrate value. In addition to adjusting the mass flow rate for each gas line during a portion of a process by providing independent setpoint flowrates to each controller 919, the gas controller 915 may provide specific setpoint values that vary based on a rotational position of the wafer carrier 903. For instance, epitaxial growth of silicon carbide may be generally described as dependent on a relatively high and even temperature across a wafer and as dependent on a even presence of precursor gasses. As a wafer or wafers rotate in a reaction chamber, they may experience different effective concentrations of precursor gasses on their surface when rotating toward the injection flange 901 compared to when rotating away from the injection flange 901. While rotating away from the injection flange 901, a portion of a wafer or wafers is moving with the flow of the precursor gasses. That movement of the portion of the wafer or wafers coinciding with the flow of the precursor gasses may encourage faster epitaxial growth at one of a leading edge or trailing edge of the wafer as the reactive components in the precursors interact with a slower moving surface. However, depending on the relative movement between the precursor gasses and the portions of the wafers, the active molecules may be depleted by a time an additional portion of the wafer or wafers encounter the precursor gasses. The result may be a change in epitaxial growth rates between the leading edge and trailing edge of a wafer or wafers based on the relative flow velocity of the precursor gasses to the surface of the wafer or wafers. By adjusting the output of one or more gas flow lines 916-918 based a relative position of wafers on the wafer carrier, the growth rate differential between the leading and trailing edges of the wafer or wafers may be adjusted. For instance, where a leading edge is found to experience more epi growth than a trailing edge, a quantity of precursor gasses from one or more nozzles (e.g., nozzle 922) may be modulated to provide a higher concentration over a trailing edge of a wafer or wafers and a lower concentration over a leading edge of the wafer or wafers. Because of the quantity of factors at play in a given reactor during a given process, modulating the flow rate of one or more nozzles based on a position of wafers on a wafer carrier at a given time may help reduce layer thickness variation while not significantly contributing new factors for consideration in equalizing grow rates across the wafers. There is a gap between the wafer pocket and the wafer edge due to tolerance of the mechanism that positions the wafers in the pockets. Variation in the placement of the wafer changes size of the gap, and hence the amount of stagnant precursor in the gap. More static precursor lingering the in gap (at circumferential locations) causes film to locally thicken; the opposite is true where the gap is relatively small. This example addresses the flow of the precursor gasses while the wafers are rotating in the same direction as the gas flow. Because of rotation of the wafer or wafers, deposition is performed with the revolver rotating, which averages heating effects and enables cross-wafer thickness control using the nozzles. The quantity of static precursor may also vary based on whether, for a given location, the wafer carrier is rotating toward or away from the injection flange 901.

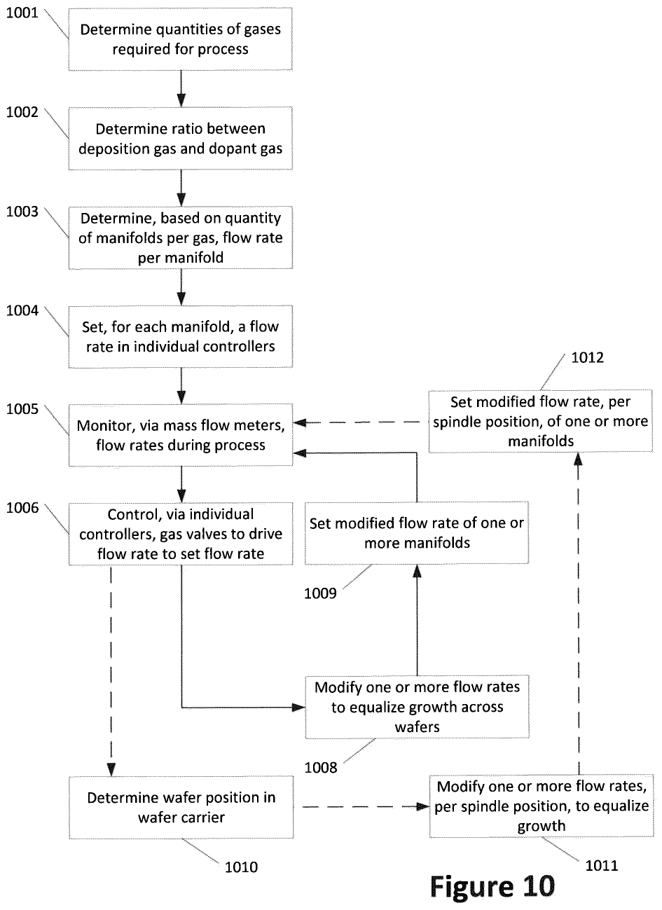

FIG. 10 is a flowchart showing illustrative processes for controlling flows of precursor gasses in a reaction chamber according to aspects of the disclosure. In step 1001, a gas controller determines quantities of gas required for a process. In step 1002, the gas controller determines the ratio between deposition gases and dopant gases. In step 1003, a gas controller determines, based on a quantity of injectors per gas, a flow rate per injector. In step 1004, the gas controller sets, for each injector, a flowrate in individual controllers. The individual controllers identified in step 1004 may be metering valves or mass flow controllers (MFC). The MFCs operate by receiving a target mass flow from the system controller, and drive to the target mass flow. The target mass flow rate may be adjusted based on changes made in step 1009.

The reaction chamber may include a single manifold (also referred to as an injection manifold). The injectors may be connected to outlets defined laterally along the injection manifold to introduce precursor into the reaction chamber. Each injector is connected to a deposition gas source (e.g., a precursor source) by one of the MFC devices described above.

In step 1005, each controller monitors, via a mass flow meter, a flowrate during the process. In step 1006, each controller controls gas valves to drive the flowrate to the set flowrate. In step 1008, one or more of the flow rates through one or more of the injectors may be modified to follow a desired recipe for a given process. In step 1009, the modified flowrate of one or more injectors is provided to a respective controller and the flow rates are monitored again in step 1005.

Alternatively or additionally, a wafer position in a wafer carrier may be determined in step 1010. Based on the wafer position in the wafer carrier in step 1010, one or more flowrates may be modified, in step 1011, per spindle position to equalize the growth of the epitaxial layer. In step 1012, the modified flowrates per spindle positions are set in one or more of the injectors.

The process of FIG. 10 may be based on deposition occurring at a known rate based on adequate supply of the precursor gasses and a desired temperature and then allow the deposition process to continue (by providing deposition gas) for period time at the known deposition rate to arrive at a desired thickness. Thickness measurement may be performed later to validate the operating conditions in the reactor chamber.

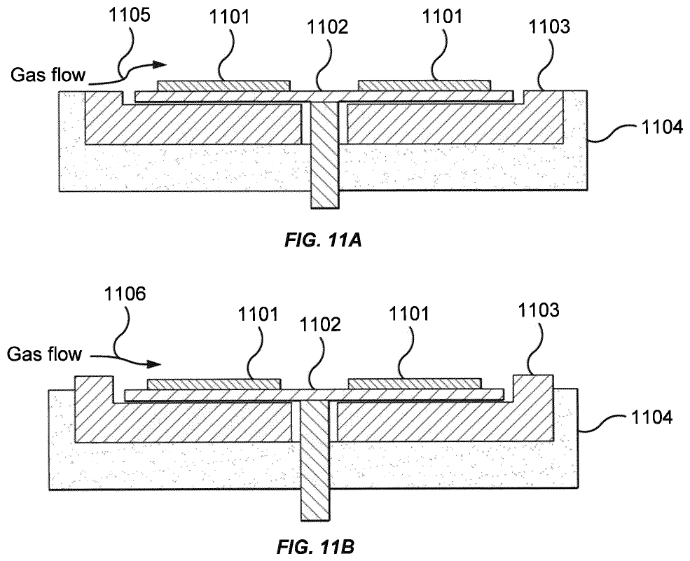

FIG. 11A depicts a first example of wafers on a wafer carrier in a reaction chamber. FIG. 11A shows wafers 1101, in a reaction chamber, on wafer carrier 1102 surrounded by a graphite wall 1103, which is surrounded by a ceramic wall 1104. The height of ceramic wall 1104 is approximately the same height as the height of graphite wall 1103. The wafer carrier 1102 lacks a lip. Precursor gasses 1105 flow up and over wafers 1101. Based on the increase in height from the edge of the graphite wall 1103 to the higher wafer 1101, the flow rate across the wafer may increase, thereby reducing the availability of the precursor gasses to an epitaxial growth process at the leading edge of wafer 1101. This may lead to a thinner epitaxial growth on the wafer edges near the periphery of the wafer carrier 1102.

FIG. 11B shows wafers 1101, in a reaction chamber, on wafer carrier 1102 surrounded by a graphite wall 1103, which is surrounded by a ceramic wall 1104. The height of ceramic wall 1104 is lower than the height of graphite wall 1103. The wafer carrier 1102 does not have a lip. Precursor gasses 1105 flow up and over wafers 1101. Based on the increase in height from the edge of the graphite wall 1103 to the higher graphite wall 1103 over the low wafer carrier 1102, and then down to wafer 1101, the flow rate across the wafer may decrease, thereby increasing the availability of the precursor gasses to an epitaxial growth process at the leading edge of wafer 1101. This may lead to a thicker epitaxial growth on the wafer edges near the periphery of the wafer carrier 1102.

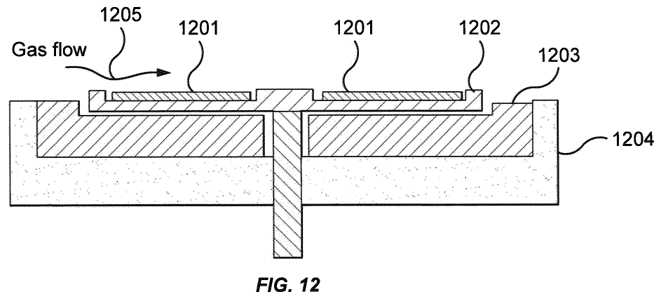

FIG. 12 depicts a third example of wafers on a wafer carrier in a reaction chamber. FIG. 12 shows wafers 1201, in a reaction chamber, on wafer carrier 1202 with a lip, which is surrounded by a graphite wall 1203, which is surrounded by a ceramic wall 1204. The height of ceramic wall 1204 is approximately the same height as the height of graphite wall 1203. Precursor gasses 1205 flow up and over the lip and then to the wafers 1201. Based on the relatively even height between the lip of the wafer carrier 1202 and the wafer 1201, the flow over the wafer 1201 may be closer to an ideal laminar flow. An issue exists with respect to spacing between the wafer carrier's lip and the edge of the wafer 1201.

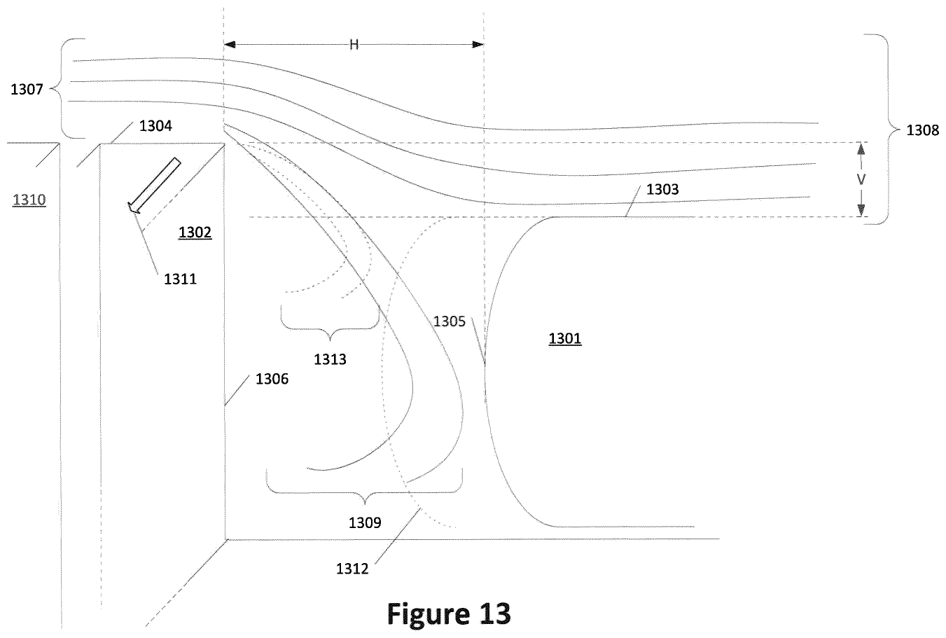

FIG. 13 depicts a flow pattern of precursor gasses around a wafer edge according to aspects of the disclosure. FIG. 13 depicts a wafer 1301 in a wafer carrier 1302 surrounded by graphite walls 1310. The height of a lip 1304 around wafer carrier 1302 (and optionally around a periphery of wafer 1301) is shown at a height taller than an upper surface 1303 of wafer 1301 by vertical distance V. Outer edge 1305 of wafer 1301 is spaced from a vertical wall 1306 of the wafer carrier 1302 by a horizontal distance H. At least three factors affect the availability of precursor gasses to the surface 1303 of the wafer 1301. The vertical height differential V permits precursor gasses to either slow down or speed up in their passage across wafer 1301. The horizontal distance differential H may increase or decrease the appearance of eddies 1309. Those eddies 1309 may permit precursor gasses to accumulate in the void between wafer 1301 and the wafer carrier 1302. As the precursor gasses accumulate, they may encourage deposition or growth of various materials that lead to wafer 1301 becoming stuck to a floor of the wafer carrier 1302. Attempting to remove the wafer 1301 with the presence of material connecting it to the floor of the wafer carrier 1302 may lead to unanticipated stresses on the wafer 1301. Those stresses may lead to catastrophic cracking of the wafer 1301 or undue strain disrupting the crystalline formation of the materials on the surface of wafer 1301. The rotational velocity 1311 of the wafer carrier 1302 may further affect the flow of precursor gasses across the surface of wafer 1301. For instance, the rotational velocity 1311 of the wafer carrier 1302 may cause the interaction of the shape of an indentation in the wafer carrier 1302 holding the wafer 1301 to concentrate the precursor gasses closer to a trailing edge of the rotating wafer 1301 compared to a leading edge of the wafer 1301. That concentration may lead to an epitaxial growth differential for each wafer 1301 in the rotation direction of the wafer carrier 1302.

The region containing eddies 1309 is the region of static flow between the wafer the pocket that varies in terms of wafer placement (the horizontal distance differential H in FIG. 13). The arcuate lines between the wafer bevel (outer edge 1305) and the interior of the pocket (vertical wall 1306) is the lingering deposition gas (precursor) that may cause localized thickening of the layer at the upper surface 1303 adjacent the wafer bevel (outer edge 1305).

As an example of how the positional error of placing the wafer 1301 in the wafer carrier 1302 is shown in dot-dash broken lines. For instance, where an outer edge 1312 of the wafer 1301 is placed closer to the vertical wall 1306, the region of static flow of the precursor gas is reduced, shown by the smaller region containing eddies 1313.

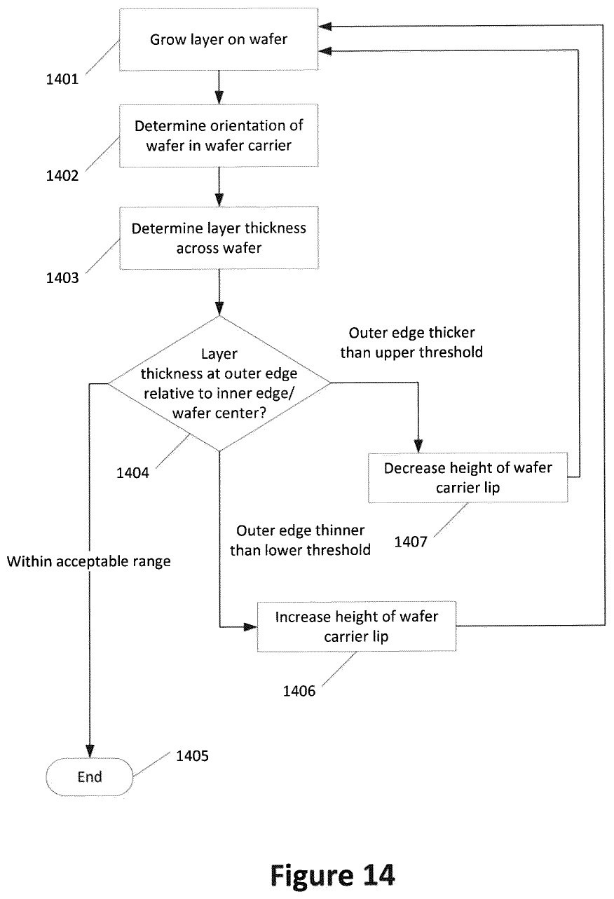

FIG. 14 is a flowchart showing an illustrative process for modifying spacings around a wafer carrier according to aspects of the disclosure. In step 1401, a layer is grown on a wafer. In step 1402, an orientation, of the wafer, in the wafer carrier is determined. In step 1403, a cross-wafer thickness variation is determined across the wafer. In step 1404, the difference in the cross-wafer thickness of the layer is checked against a difference threshold. If from step 1404, the threshold difference is within an acceptable range, then the process ends in step 1405. If the outer edge of the wafer is out of a desired range, then then deposition gas flow rate may be adjusted at the injection flange according to the cross-wafer thickness variation using the apparatus of FIG. 8 to obtain the effect of FIG. 9.

Alternatively or additionally, if the outer edge of the wafer is thicker than an upper threshold from step 1404, then the height of the wafer carrier lip is decreased in step 1407 and the process is repeated in step 1401. If the outer edge of the wafer is thinner than a lower threshold, then the height of the carrier lip is increased in step 1406 and the process is repeated.

Step 1404 may be performed in a radial direction of the wafer carrier and/or in a rotational direction of the wafer carrier. An advantage of performing step 1404 in multiple directions with respect to the wafer may permit adjustments to the lip of the wafer carrier on various sides relative to the position of wafers.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A system comprising:
a plurality of reactor modules configured to perform semiconductor processes on wafers;
a plurality of loading/unloading stations;
one or more load/lock chambers configured to modify a temperature of the wafers;
a substrate handling chamber comprising a first substrate transfer assembly, wherein the first substrate transfer assembly is configured to transfer the wafers between the plurality of reactor modules and the one or more load/lock chambers; and
a transfer chamber comprising a second substrate transfer assembly, wherein the second substrate transfer assembly is configured to transfer the wafers between the plurality of loading/unloading stations and the one or more load/lock chambers.

2. The system of claim 1, wherein the first substrate transfer assembly is configured to transfer the wafers individually between the reactor modules and the one or more load/lock chambers.

3. The system of claim 1, wherein the first substrate transfer assembly is configured to transfer the wafers on a wafer carrier between the reactor modules and the one or more load/lock chambers.

4. The system of claim 1, wherein the one or more load/lock chambers are configured to both heat and cool wafers.

5. The system of claim 1, wherein the one or more load/lock chambers comprise:
a heating load/lock chamber configured to heat wafers; and
a cooling load/lock chamber configured to cool wafers.

6. A method comprising:
receiving, at a loading station, a plurality of wafers at a first temperature;
transferring, via a first substrate transfer assembly, the plurality of wafers to a load/lock station;
heating, from the first temperature to a second temperature, the wafers in the load/lock station;
transferring, via a second substrate transfer assembly, the wafers from the load/lock station to a first reactor module, wherein the first reactor module comprises a first reaction chamber;
heating, in the first reactor module and from the second temperature to a third temperature, the wafers;
performing a first semiconductor production process on the wafers;
transferring, via the second substrate transfer assembly, the wafers to the load/lock station;
cooling, to a temperature lower than the third temperature, the wafers; and
transferring, via the first substrate transfer assembly, the plurality of wafers to the loading station.

7. The method of claim 6,
wherein the load/lock station comprises a heating load/lock station and a cooling load/lock station,
wherein the heating is performed in the heating load/lock station, and
wherein transferring the wafers from the load/lock station to the first reactor module comprises:
transferring the wafers from the heating load/lock station to the first reactor module.

8. The method of claim 7, wherein transferring the wafers from the first reactor module to the load/lock station comprises:
transferring the wafers from the first reactor module to the cooling load/lock station.

9. The method of claim 6,
wherein the lower temperature is a temperature at which the wafers are unloaded, and
wherein the second temperature is higher than the lower temperature.

10. The method of claim 6, further comprising:
transferring, after performing the first process on the wafers and via the second substrate transfer assembly, the wafers from the first reactor module to a second reactor module;
heating, in second reactor module and to a fourth temperature, the wafers; and
performing a second process on the wafers,
wherein transferring the wafers to the load/lock station further comprises transferring the wafers from the second reactor module to the load/lock station.

11. The method of claim 6,
wherein the first temperature is room temperature,
wherein the second temperature is approximately 400° C.±50° C., and
wherein the third temperature is at or above 1200° C.

12. The method of claim 6, wherein performing the first process on the wafers comprises:
etching the wafers;
conditioning the first reaction chamber;
heating the wafers to a fourth temperature; and
epitaxially growing silicon carbide on the wafers.

13. The method of claim 12,
wherein the fourth temperature is at or above 1750° C.

14. A system comprising:
a reactor chamber comprising outer walls and inner walls;
a wafer carrier configured to support one or more wafers;
a spindle configured to rotate the wafer carrier;
graphite walls above and below the wafer carrier, wherein the inner walls and the graphite walls define a gas flow path;
a susceptor above and below the graphite walls;
two or more coils configured to inductively heat the susceptor;
a power supply configured to energize the coils;
two or more pyrometers configured to measure temperatures of the graphite wall; and
a temperature controller configured to control, based on the temperatures and via the power supply, power supplied to at least one of the coils.

15. The system of claim 14, wherein the susceptor comprises a ceramic material.

16. The system of claim 14, wherein the temperature controller is configured to control the power supplied to the at least one of the coils based on a temperature differential between the two or more pyrometers.

17. The system of claim 14,
wherein the two or more pyrometers comprise three or more pyrometers configured to measure temperatures of the graphite walls; and
wherein the temperature controller is configured to control the power supplied to the at least one of the coils based on a temperature gradient of the graphite walls.

18. The system of claim 14,
wherein the two or more pyrometers are spaced in a radial direction outward from an axis of the spindle.

19. A method comprising:
powering two or more sets of coils to inductively heat a susceptor;
receiving, from two or more pyrometers, signals relating to temperatures of graphite walls, wherein the graphite walls are heated by the susceptor;
determining, based on the signals, a temperature differential;
determining whether the temperature differential satisfies a threshold; and
controlling, based on a determination that the temperature differential satisfies the threshold, power supplied to at least one set of the two or more sets of coils.

20. The method of claim 19, wherein receiving signals further comprises:
receiving, from three or more pyrometers, signals relating to temperatures of the graphite walls,
wherein determining the temperature differential comprises determining a temperature gradient across the graphite walls, and
wherein determining whether the temperature differential satisfies a threshold comprises determining whether the temperature gradient satisfies a temperature gradient threshold.

21. A method comprising:
selecting a first wafer carrier comprising a first wafer support surface, configured to support a wafer, and a first horizontal lip surface parallel to and elevated, by a first vertical distance, from the first wafer support surface;
growing, in a reactor and on an upper surface of the wafer, an epitaxial layer, wherein the wafer is supported, in the reactor, by the first wafer support surface of the first wafer carrier, wherein the first wafer carrier is rotated in the reactor about a center of rotation;
determining, from a circumferential edge and in a radial direction of the first wafer carrier, thicknesses of the epitaxial layer at two or more locations of the wafer;
determining a slope in thickness between the two or more locations of the wafer;
determining that the slope does not satisfy a range of acceptable slopes;
determining, based on a direction of the slope, one of an increase or decrease in elevation between the first horizontal lip surface of the first wafer carrier and the upper surface of the wafer;
generating an alert identifying a determination of the increase or decrease in elevation; and
selecting a second wafer carrier with second wafer support surface and a second horizontal lip surface and elevated, by a second vertical distance, from the second wafer support surface, wherein a difference between the first vertical distance and the second vertical distance comports with the determination of the increase or decrease in elevation.

22. The method of claim 21, further comprising:
growing, in the reactor, a second epitaxial layer on a second wafer supported by the second wafer support surface of the second wafer carrier;
determining, from the circumferential edge and in a radial direction of the second wafer carrier, thicknesses of the epitaxial layer at two or more locations of the second wafer;
determining a second slope in thickness between at the two or more locations of the second wafer;
determining that the second slope does not satisfy the range of acceptable slopes;
determining, based on a direction of the slope, one of an increase or decrease in elevation between the second horizontal lip surface of the second wafer carrier and the upper surface of the second wafer; and
generating a second alert identifying a second determination of the increase or decrease in elevation.

23. The method of claim 21,
wherein determining the thicknesses of the epitaxial layer comprises:
determining the thicknesses of the epitaxial layer at multiple locations; and
determining a thickness profile of the epitaxial layer, and
wherein determining the slope comprises:
determining an interior slope of the epitaxial layer between two locations, each location spaced from endpoints of the thickness profile.

24. The method of claim 21,
wherein determining the thicknesses of the epitaxial layer comprises:
determining the thicknesses of the epitaxial layer at multiple locations; and
determining a thickness profile of the epitaxial layer, and
wherein determining the slope comprises:
determining an exterior slope of the epitaxial layer between two locations, each location at an endpoint of the thickness profile.

25. The method of claim 21,
wherein the first wafer carrier is configured to support one wafer.

26. The method of claim 21,
wherein the first wafer carrier is configured to support three or more wafers.

27. The method of claim 26, further comprising:
determining, from a leading edge of one of the three or more wafers in rotational direction of the first wafer carrier, thicknesses of the epitaxial layer at two or more locations of the one of the three or more wafers;
determining a second slope in thickness between the two or more locations of the one of the three or more wafers;
determining that the second slope does not satisfy the range of acceptable slopes;
determining, based on a direction of the second slope, one of an increase or decrease in elevation between the first horizontal lip surface of the first wafer carrier and the upper surface of the one of the three or more wafers;
generating a second alert identifying a second determination of the increase or decrease in elevation; and
selecting a third wafer carrier with third wafer support surface and a third horizontal lip surface and elevated, by a third vertical distance, from the third wafer support surface, wherein a difference between the first vertical distance and the third vertical distance comports with the second determination of the increase or decrease in elevation.

28. The method of claim 21,
wherein the first wafer carrier comprises a first vertical inner surface spaced from a vertical edge of the wafer by a first horizontal distance, and
the method further comprising:
determining, from the thicknesses, a presence of a hill or trough in the epitaxial layer of the wafer near the circumferential edge of the first wafer carrier;
determining that an elevation of the hill or trough exceeds a range of acceptable elevations of hills and troughs;
determining, based on the hill or trough, one of an increase or decrease in the first horizontal distance;
generating a second alert identifying a second determination of the increase or decrease in the first horizontal distance; and
selecting, based on the determination of the increase or decrease in the first horizontal distance, a third wafer carrier with second vertical inner surface configured to be spaced from a vertical edge of a second wafer by a second horizontal distance,
wherein a difference between the first horizontal distance and the second horizontal distance comports with the second determination of the increase or decrease in horizontal distance.
